(19) United States
(12) Patent Application Publication
(10) Pub. No.: US 2024/0274563 A1
(43) Pub. Date: Aug. 15, 2024

(54) SOLDER STRUCTURE WITH DISRUPTABLE COATING AS SOLDER SPREADING PROTECTION

(71) Applicant: Infineon Technologies AG, Neubiberg (DE)

(72) Inventors: Hock Heng CHONG, Melaka (MY); Hui Khin TAN, Melaka (MY); Chee Yang NG, Johor (MY); Swee Kah LEE, Melaka (MY)

(73) Assignee: Infineon Technologies AG, Neubiberg (DE)

(21) Appl. No.: 18/415,880

(22) Filed: Jan. 18, 2024

(30) Foreign Application Priority Data
Feb. 9, 2023 (DE) 10 2023 103 161.9

(51) Int. Cl. H01L 23/00

(52) U.S. Cl. CPC H01L 24/13; H01L 24/16; H01L 24/40; H01L 24/81; H01L 24/84; H01L 2224/13109; H01L 2224/13111; H01L 2224/13139; H01L 2224/13144; H01L 2224/13147; H01L 2224/13155; H01L 2224/1357; H01L 2224/13686; H01L 2224/16227; H01L 2224/40227; H01L 2224/40245; H01L 2224/40499; H01L 2224/81815; H01L 2224/84815; H01L 2924/014; H01L 2924/0536; H01L 2924/0541; H01L 2924/0543; H01L 2924/0544; H01L 2924/20106; H01L 2924/20107; H01L 2924/20108

(57) ABSTRACT

A solder structure and method is disclosed. In one example, the solder structure includes a solder material, and a coating which at least partially coats the solder material and is configured for protecting the solder material against solder spreading. The coating is at least partially disrupted when establishing a solder connection between the solder material and a solderable structure.

### CROSS-REFERENCE TO RELATED APPLICATION

This Utility Patent Application claims priority to German Patent Application No. 10 2023 103 161.9 filed Feb. 9, 2023, which is incorporated herein by reference.

### BACKGROUND

### Technical Field

Various embodiments relate generally to a solder structure, an electronic device, and a method of manufacturing an electronic device.

### Description of the related art

A conventional package may comprise an electronic component mounted on a chip carrier such as a leadframe, may be electrically connected by a bond wire extending from the chip to the chip carrier, and may be molded using a mold compound as an encapsulant.

Undesired spreading of solder in unwanted portions of a package may be an issue when creating a solder connection, for instance between a carrier and an electronic component.

### SUMMARY

There may be a need for suppressing spreading of solder in unwanted portions of a package.

According to an exemplary embodiment, a solder structure is provided which comprises a solder material, and a coating which at least partially coats the solder material and is configured for protecting the solder material against solder spreading and for being at least partially disrupted when establishing a solder connection between the solder material and a solderable structure.

According to another exemplary embodiment, an electronic device is provided which comprises a first functional body, a second functional body, and a solder structure comprising solder material which establishes a solder connection in a solder connection region between the first functional body and the second functional body, wherein a coating of the solder structure partially coats the solder material apart from the solder connection region, and wherein the coating is configured for protecting the solder material against solder spreading.

According to still another exemplary embodiment, a method of manufacturing an electronic device is provided, wherein the method comprises providing a solder structure having the above mentioned features between a first functional body and a second functional body, establishing a solder connection by the solder material in a solder connection region between the first functional body and the second functional body while at least partially (i.e. only partially or entirely) disrupting the coating in the solder connection region, and protecting the solder material by the coating against solder spreading during establishing the solder connection.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a solder structure according to an exemplary embodiment.

FIG. 2 illustrates a cross-sectional view of an electronic device according to an exemplary embodiment.

FIG. 3 illustrates a cross-sectional view of an electronic device according to another exemplary embodiment.

FIG. 4 illustrates a cross-sectional view of an electronic device according to still another exemplary embodiment.

FIG. 5 illustrates a cross-sectional view of an electronic device according to yet another exemplary embodiment.

FIG. 6 illustrates an image of a morphological adhesion promoter as coating of a solder structure according to an exemplary embodiment.

FIG. 7 illustrates another image of a morphological adhesion promoter as coating of a solder structure according to an exemplary embodiment.

FIG. 8 illustrates an image showing a bare leadframe surface subjected to solder spreading.

FIG. 9 illustrates another image showing protection against solder spreading in an electronic device according to an exemplary embodiment.

### DETAILED DESCRIPTION

According to an exemplary embodiment, a solder structure is provided which comprises a solder material, and a coating which at least partially coats the solder material and is configured for protecting the solder material against solder spreading and for being at least partially disrupted when establishing a solder connection between the solder material and a solderable structure.

According to another exemplary embodiment, an electronic device is provided which comprises a first functional body, a second functional body, and a solder structure comprising solder material which establishes a solder connection in a solder connection region between the first functional body and the second functional body, wherein a coating of the solder structure partially coats the solder material apart from the solder connection region, and wherein the coating is configured for protecting the solder material against solder spreading.

According to still another exemplary embodiment, a method of manufacturing an electronic device is provided, wherein the method comprises providing a solder structure having the above mentioned features between a first functional body and a second functional body, establishing a solder connection by the solder material in a solder connection region between the first functional body and the second functional body while at least partially (i.e. only partially or entirely) disrupting the coating in the solder connection region, and protecting the solder material by the coating against solder spreading during establishing the solder connection.

According to an exemplary embodiment, a solder structure-for instance for connecting functional bodies of a package by soldering-is provided with a coating on a solder material. Advantageously, said coating may function for protecting the solder material against solder spreading during and after the soldering process by inhibiting still flowable solder material from flowing away from a solder position, in particular laterally. This may prevent solder material from flowing into undesired regions apart from a solder position, for instance into regions which shall remain free of solder material. This may avoid, in turn, the formation of undesired electrically conductive bridges between portions of a package which shall remain electrically insulated with respect to each other. Furthermore, the coating may be advantageously configured so that it will be disrupted partially or entirely upon or by establishing a solder connection between the solder material and a solderable structure. This may allow for efficiently suppressing spreading of solder in unwanted portions of a package. Cumbersome conventional countermeasures against solder spreading, such as the formation of a solder resist, may be optionally omitted. Advantageously, a local disruption of the coating or part thereof may be achieved automatically and merely by the conditions during soldering (in particular the temperature conditions during soldering) without the need of taking additional measures.

### Description of Further Exemplary Embodiments

In the following, further exemplary embodiments of the solder structure, the electronic device, and the method will be explained.

In the context of the present application, the term “solder structure” may particularly denote any physical structure (for example a pad, a bump or a layer) being configured for creating a solder connection.

In the context of the present application, the term “solder material” may particularly denote a material which is configured so that it can form a solder connection. For example, a solder material may comprise or consists of tin. In particular, a solder material may comprise a fusible or fused metal or metal alloy suitable to create a permanent bond between two functional bodies, which may be metallic workpieces. A solder material may be melted in order to wet the functional bodies to be joint, wherein the solder material may adhere to and connect the functional bodies after cooling. Metals and/or alloys appropriate for use as solder material may have a lower melting point than the functional bodies to be joined.

In the context of the present application, the term “coating” may particularly denote a structure at least partially covering solder material. For example, a coating may be a layer or a thin film which may form part of an exterior surface of the solder structure.

In the context of the present application, the term “coating configured for protecting the solder material against solder spreading” may particularly denote that the coating is provided so that it inhibits or even eliminates a spatial spreading of flowable solder material beyond limits of the solder structure defined by the coating. In other words, the coating may function as a barrier for flowable solder material preventing the flowable solder material from laterally flowing or flowing significantly beyond side walls of the solder structure.

In the context of the present application, the term “coating configured for being at least partially disrupted when establishing a solder connection” may particularly denote that the coating is formed so that conditions of establishing a solder connection between functional bodies by the solder structure may cause the coating to be disrupted partially or entirely to thereby create an at least partially direct physical contact between the solder material and a functional body to be connected. In other words, the coating may be intentionally destroyed, sacrificed or removed selectively and at least partially in a connection region between the solder structure and a functional body to be connected by soldering.

In the context of the present application, the term “electronic device” may particularly denote a structure, body or arrangement of a plurality of structures and/or bodies fulfilling an electric or electronic function. In particular, such an electronic device may be configured for enabling a controlled flow of electric current and/or electric signals. For example, the electronic device is a package, in particular a semiconductor package comprising at least one encapsulated semiconductor component.

In the context of the present application, the term “functional body” may in particular denote any constituent or member of an electronic device contributing to the electronic function of the electronic device. Such a functional body may for instance be an encapsulated electronic component, such as a semiconductor chip. Another example for a functional body is a carrier carrying an electronic component, for instance a leadframe-type carrier. Yet another example for a functional body is an electrically conductive connection structure, such as a clip or a bond wire, used for connecting an electronic component with a carrier.

In an embodiment, the coating comprises an adhesion promoter. In the context of the present application, the term “adhesion promoter” may particularly denote any material and/or measure enhancing adhesion. More specifically, such an adhesion promoter provided by the solder structure coating may act as an interface between the solder material of the solder structure and a surrounding. Consequently, the coating may fulfil the additional function of promoting adhesion with a connected medium, for instance an encapsulant (such as a mold compound).

In an embodiment, the coating comprises an inorganic adhesion promoter. In the context of the present application, the term “inorganic” may particularly denote a coating made of material that lacks carbon-hydrogen bonds, i.e. that is not an organic compound.

In an embodiment, the coating comprises a morphological adhesion promoter. In the context of the present application, the term “morphological adhesion promoter” may particularly denote an adhesion promoter having a morphological structure. In the context of the present application, the term “morphological structure” may particularly denote a structure having a topology and/or porous structure and/or being shaped in such a way so as to increase the connection surface between connection partners. Moreover, the morphology of a morphological adhesion promoter may cause an advantageous mechanical interlocking between connection partners. In other words, a morphological structure promotes adhesion due to its shape, rather than only promoting adhesion due to its chemistry. However, it is also possible that a morphological structure is synergistically made of material which, in view of its intrinsic properties, promotes adhesion additionally to the shape. In particular, a morphological adhesion promoter may be a porous material. The porosity of the morphological adhesion promoter may enhance its adhesion promoting properties.

In an embodiment, the morphological adhesion promoter comprises at least one of the group consisting of a metallic structure, an alloy structure, a chromium structure, a vanadium structure, a molybdenum structure, a zinc structure, a manganese structure, a cobalt structure, a nickel structure, a copper structure, a flame deposited structure, a roughened metal structure (in particular a roughened copper structure or a roughened aluminum oxide structure), and any oxide, nitride, carbide, and selenide of any of said structures. All structures may comprise or consist of these metals and/or the alloys thereof. In addition, these structures may comprise or consist of these metals and their alloy-oxides. In particular, single oxides and mixed oxides are possible in different embodiments. Whether the alloy oxidizes or not may depend on the thermal budget in production. However, other materials and structures may be used for the morphological adhesion promoter as well. The above-mentioned flame deposited structure may comprise or consist of silicon dioxide, any titanium oxide (such as for instance TiO₂, TiO, TiₓO_{y}), etc. Any organometallic precursor can be used that can be burned in a mixture with a burning gas such as propane or butane and form the specific metal oxide.

In particular, a morphological adhesion promoter may be formed at an exterior surface of the solder material using Atomic Layer Deposition (ALD), Chemical Vapor Deposition (CVD), etc.

Advantageously, an adhesion promoting coating may function as a powerful coating for strongly suppressing solder spreading during a soldering process. At the same time, such a material can be advantageously disrupted where a solder connection is created.

In an embodiment, the coating comprises an oxide layer. By forming an oxide layer on the solder material of the solder structure, a coating with solder spreading inhibiting properties and the capability of being mechanically weakened or disrupted triggered by the local conditions of a soldering process may be formed in a simple way. The oxide layer may be preferably an oxide of another material (in particular of another metallic material) than the solder material. This may allow to adjust the properties of the solder material and of the coating individually.

In an embodiment, the oxide layer comprises a metal oxide or a semiconductor oxide. The metal oxide may comprise copper oxide, aluminum oxide, zinc oxide chromium oxide, zinc oxide vanadium oxide, zinc oxide molybdenum oxide, zinc oxide manganese oxide, and/or zinc oxide tungsten oxide. The semiconductor oxide may for example comprise silicon oxide. Other materials are possible, provided that a corresponding oxide inhibits solder spreading and undergoes self-destruction upon soldering.

In an embodiment, the solder material has a thickness in a range from 5 μm to 100 μm, in particular in a range from 10 μm to 50 μm. Furthermore, the coating may have a thickness in a range from 10 nm to 500 nm, in particular in a range from 50 nm to 200 nm. Hence, the coating may be significantly thinner than the solder material. For example, a thickness of the solder material may be at least 10 times, in particular at least 100 times, of a thickness of the coating. Such a thin coating may be prone to self-destruction upon soldering, and may nevertheless be capable of efficiently inhibiting solder spreading during soldering.

In an embodiment, the solder material comprises tin or a tin alloy, in particular at least one of the group consisting of AgSn, AuSn, NiSn, CuSn, AgCuSn, and InSn. Tin may have excellent solder properties. At least one additional metallic constituent may refine the properties of the solder material.

In an embodiment, the first and/or the second functional body comprises an electronic component. For example, the electronic component may be mounted on a carrier. In the context of the present application, the term “electronic component” may in particular encompass a semiconductor chip (in particular a power semiconductor chip), an active electronic component (such as a transistor), a passive electronic component (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc.

In an embodiment, the first and/or the second functional body comprises a carrier. In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. For instance, such a carrier may be a leadframe (for instance made of copper), a DAB (Direct Aluminum Bonding), DCB (Direct Copper Bonding) substrate, etc. Also at least part of the carrier may be encapsulated by an encapsulant, together with the electronic component.

In an embodiment, the first and/or the second functional body comprises a clip. A clip may be a curved electrically conductive body accomplishing an electric connection with a high connection area to an upper main surface of a respective electronic component. Additionally or alternatively to such a clip, it is also possible to implement one or more other electrically conductive interconnect bodies in an electronic device, for instance a bond wire and/or a bond ribbon connecting an electronic component with a die pad and/or a lead or connecting different pads of an electronic component.

In an embodiment, one of the first functional body and the second functional body is an electronic component and the other one of the first functional body and the second functional body is a carrier. In particular, chip assembly on a carrier may be accomplished by a solder structure according to an exemplary embodiment. For example, the solder material may be used for interconnecting a semiconductor chip with a substrate or a leadframe.

In an embodiment, one of the first functional body and the second functional body is a clip and the other one of the first functional body and the second functional body is a carrier. For example, the solder material may be used for interconnecting a metallic clip (for instance a bent metal plate) with a substrate or a leadframe.

In an embodiment, the carrier is a laminate substrate or a leadframe structure. For example, a leadframe structure may be a structured metal plate. Preferably, such a leadframe-type carrier comprises a die paddle or die pad, on which an electronic component may be mounted. Furthermore, such a leadframe-type carrier may comprise at least one lead, preferably a plurality of leads. A leadframe structure may be a metal structure of the package that carries signals from the electronic component to the outside, and/or in opposite direction. A laminate substrate may be a plate-shaped carrier formed by laminating a plurality of dielectric sheets (for instance prepreg sheets) and metallic sheets (for instance copper sheets).

In an embodiment, the carrier comprises a metal structure, in particular a metal structure with a metallic surface coating. When the carrier is metallic, it may be used directly for creating a solder connection with another functional body. A metallic surface coating may for instance be a plating layer on a surface of a metallic sheet or plate which may fine-tune the surface properties of the carrier. For instance, the metallic surface plating may provide corrosion and/or oxidation resistance and/or may equip the carrier itself with solderable material.

In an embodiment, one of the first functional body and the second functional body is an electronic component and the other one of the first functional body and the second functional body is a clip. For example, the solder material may be used for interconnecting a semiconductor chip with a metallic clip (for instance a bent metal plate).

In an embodiment, the electronic device is free of a solder resist. A solder resist or solder mask may be a thin lacquer-like layer of polymer that may be conventionally applied to a surface of a functional body subjected to soldering for protection against oxidation and to prevent solder bridges from forming between closely spaced solder pads. A solder bridge may be an unintended electrical connection between two conductors by solder. While conventional electronic devices may use solder masks to prevent solder bridges and may accept issues introduced by a solder mask, exemplary embodiments may allow to omit a solder mask, since the avoidance of solder bridges may be accomplished by the coating being configured for protecting against solder spreading. Thus, exemplary embodiments may have the opportunity to omit a solder resist.

Alternatively, other exemplary embodiments may use a solder resist in addition to the provision of the solder spreading protection coating. For example, this may be appropriate when the avoidance of solder bridges is desired or required with highest reliability.

In an embodiment, the coating of the solder structure coats at least sidewalls of the solder material. In particular in an interface region between functional bodies to be connected by the solder structure, the coating may be destroyed partially or entirely during the soldering process, whereas it may remain functional and intact apart from an actual solder position on the sidewalls of the solder structure. This may be the result of different temperatures, mechanical pressures and/or mechanical impacts at an actual solder position as compared with sidewall regions apart from the actual solder position. In the readily manufactured electronic device, the coating may remain only outside of solder-connected surfaces of the interconnected functional bodies, whereas the coating may be sacrificed for achieving very low contact resistance at the solder-connected surfaces of the interconnected functional bodies.

In an embodiment, the solder structure forms part of one or both of the first functional body and the second functional body. In one embodiment, only one of the interconnected functional bodies may be provided with solder material and the coating having the properties as described herein, whereas the cooperating other functional body may be free of such a solder structure. This may lead to a very thin solder connection and thus short connection paths. Alternatively, both cooperating functional bodies may be provided with a respective solder structure resulting in an excellent connection reliability.

In an embodiment, the electronic device is configured as a package, in particular a semiconductor package, more particularly a semiconductor power package. For example, the package is configured as power module, for instance molded power module such as a semiconductor power package.

In an embodiment, the electronic device or package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the electronic device according to an exemplary embodiment is fully compatible with standard packaging concepts (in particular fully compatible with standard TO packaging concepts) and appears externally as a conventional package, which is highly user-convenient.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the electronic device comprises an encapsulant at least partially encapsulating the first functional body, the second functional body, and/or the solder structure. In the context of the present application, the term “encapsulant” may particularly denote a substantially electrically insulating material surrounding at least part of the aforementioned constituents to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In an embodiment, the method comprises establishing the solder connection by heating the solder material above its melting point which at least partially disrupts the coating in the solder connection region. A heating temperature may be particularly high where the solder structure is in direct physical contact with a functional body to be connected by the solder structure. This and/or a contact pressure may promote a selective disruption of the coating in the connection region.

In an embodiment, the method comprises establishing the solder connection by heating the solder material to a temperature in a range from 230° C. to 270° C., in particular in a range from 240° C. to 260° C., which at least partially disrupts the coating in the solder connection region. Caused or promoted by the mentioned high temperatures, fresh solder underneath can form an interconnection with a respective surface. The coating can further protect against solder spreading during this process.

In an embodiment, the method comprises establishing the solder connection and at least partially disrupting the coating in the solder connection region by reflow soldering. Reflow soldering may involve conditions at a solder connection position between functional bodies which may cause the coating to disrupt.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of semiconductor processing technologies such as appropriate etching technologies (including isotropic and anisotropic etching technologies, particularly plasma etching, dry etching, wet etching), patterning technologies (which may involve lithographic masks), deposition technologies (such as Chemical Vapor Deposition (CVD), Plasma Enhanced Chemical Vapor Deposition (PECVD), Atomic Layer Deposition (ALD), sputtering, etc.).

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

In conventional approaches, the spatial definition of a pad opening may be required for confinement of solder spreading. This may allow to maintain a bond line thickness (BLT) between chip terminal and leadframe or substrate landing pad. A thin bond line thickness may impact solder joint robustness and life span of copper pillar devices.

Conventional approaches may further use a solder mask as pad opening. However, this may cause issues with a pad. In particular, pad budging issues may occur during mold transfer molding due to low or no support between a landing pad and a mold cavity surface which may be caused by a solder mask thickness spacing (for instance in a range from 6 μm to 12 μm). This may cause the risk of a solder joint crack between chip and substrate.

Furthermore, conventional approaches may suffer from limitations of solder mask material properties. Moisture absorption may lead to package delamination or cracks in a solder mask region during reflow. Hence, there may be limitations concerning product moisture sensitivity level.

According to an exemplary embodiment, an electronic device (such as a package) may be provided with a solder structure between functional bodies (such as a carrier and an electronic component). The mentioned solder structure may comprise an actual solder material which forms a solder connection between the functional bodies. Advantageously, a coating of the solder structure partially coats the solder material apart from a solder connection region where the functional bodies are connected by soldering. In the solder connection region, the coating may be self-destructed by the soldering process. Advantageously, the coating may protect the solder material against solder spreading, i.e. against flow of solder to undesired regions. Hence, an exemplary embodiment provides a coating on a solder material which functions as a solder wetting stopper. For instance, the solder structure may be configured as a solderable pad with a thin coating opened by self-destruction during soldering. As a consequence of said self-destruction, the solder material of the solder structure may be brought in contact with a solderable metal surface. Advantageously, the coating may remain intact apart from a solder region, in particular at sidewalls of the solder material. For example, the coating may be formed on the solder material by an appropriate pretreatment.

In an electronic device according to an exemplary embodiment, a disrupted coating pad opening may be formed on solder material (such as a tin or solder plated surface) for an interconnection between functional bodies (for example a clip-to-chip terminal bonding interconnect).

A corresponding coating may be embodied as a specific oxide (in particular a metal oxide or a semiconductor oxide). It is also possible that the coating is a morphological adhesion promoter. Preferably, said coating may be free of chromium. It is possible to provide the coating also on a treated surface (for example a micro plated leadframe with ENIG/Cu/UppF/Ag profile). The coating may be rough or smooth. In the readily manufactured electronic device, the coating may be present at side walls of the pads or the pad cavity. Such a coating may function as a solder bleed stopper which may render a conventional solder mask dispensable or may be used for enhanced reliability in combination with a solder mask.

Hence, an exemplary embodiment may provide a solder structure having a coating being configured to stop solder bleed without the absolute need of using a solder mask on solder material. In particular, a solder material may be provided with an oxide coating or a coating in form of a morphological adhesion promoter. It is also possible to provide the coating by a mask. The coating may be configured to break when the solder material (for example tin) melts. The result may be a disrupted coating pad opening on solder material (such as tin or a solder plated surface) for providing a solder connection between functional bodies. For instance, a chip terminal bonding interconnection may be formed using such a solder structure. For example, the coating may remain-after soldering-on the side walls of a soldered pad or on a pad cavity. Another portion of the coating may be disrupted at a solder connected pad or on a solder plated surface. Advantageously, the surface coating results in a prevention of a spreading of the solder material when being flowable during the soldering process. Furthermore, the presence of the coating may improve mold adhesion and may protect a carrier (for example leadframe) surface from oxidation.

Descriptively speaking, the coating of the solder structure may serve as solder bridging prevention. This may be in particular advantageous for high pin count pad density defined printed circuit board (PCB)-type pads with close pad clearance. Descriptively speaking, this may enable a high temperature reflow beyond solder mask limit. Furthermore, the coating may provide a resistance to dendritic formation. Beyond this, the coating may act as corrosion and/or oxidation barrier.

Exemplary applications of exemplary embodiments are land grid array packages and/or metal pillar flip chip devices. Furthermore, since electronic devices according to exemplary embodiments may be formed with high reliability, corresponding packages may be used in particular for automotive products, industrial products, flip chips devices, etc.

An exemplary embodiment may provide a package with high robustness and very reliable solder joint quality. A desirable solder bond line thickness may be obtained on a carrier (such as a substrate or leadframe). Conventional solder mask material property limitations, such as moisture absorption leading to package delamination or cracks in a solder mask region during reflow, may be overcome since a solder mask may be omitted.

Furthermore, a simple surface plating or treatment on a functional body (for example a carrier such as a leadframe, a substrate, or input/output pads of an electronic component) may be carried out for forming a coating that serves as solder spreading stopper and at the same time protects a surface from oxidation. Moreover, said coating may provide an improved mold compound adhesion robustness.

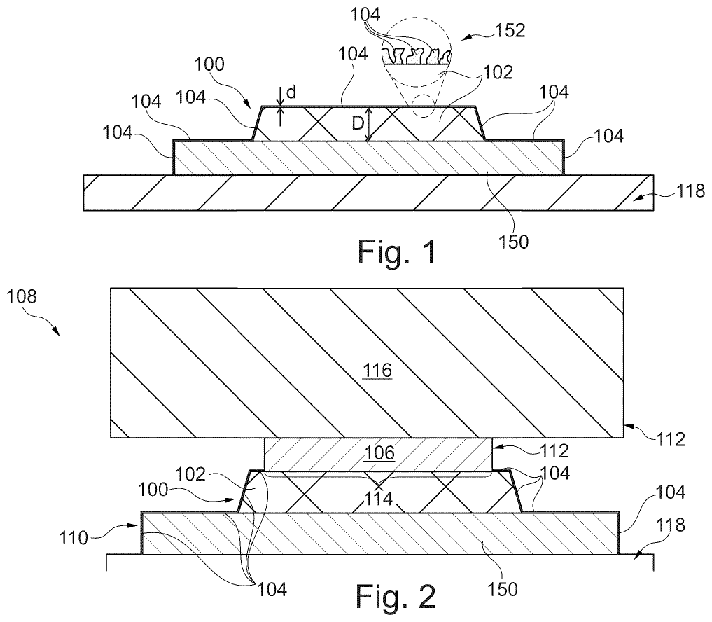

FIG. 1 illustrates a solder structure 100 according to an exemplary embodiment.

More specifically, the solder structure 100 shown in FIG. 1 is formed on a landing pad 150 of a carrier 118, such as a laminate-type core material. It is also possible that the carrier 118 is a leadframe structure. For instance, landing pad 150 may be made of copper, for example plated copper. More generally, landing pad 150 can be pure metallic body or can be made of a metal (such as copper) with a plating thereon (for example ENIG, electroless nickel immersion gold).

The solder structure 100 on the carrier 118 comprises a solder material 102. For example, solder material 102 may be plated tin or an appropriate tin alloy. The solder material 102 may be capable of being made flowable by heating to thereby form a solder connection between the landing pad 150 and a functional body to be interconnected (not shown in FIG. 1) via the solder structure 100.

Furthermore, a coating 104 is provided which coats an exposed surface of the solder material 102, and optionally an exposed surface of the landing pad 150. Advantageously, the coating 104 is configured for protecting the solder material 102 against solder spreading during a soldering process. Thus, when the solder material 102 becomes flowable by heating above its melting point, the coating 104 acts as a barrier for preventing a flow of solder material 102 significantly beyond the lateral limits of the solder structure 100. Furthermore, the material of the coating 104 may be advantageously configured for being disrupted when and where establishing a solder connection between the solder material 102 and a solderable structure. Descriptively speaking, the coating 104 may be self-destroyed at a connection interface between the solder structure 100 and a functional body (not shown in FIG. 1) to be interconnected therewith. This may lead advantageously to an electrically conductive connection between the solder structure 100 and the functional body with low contact resistance. At the same time, the coating 104 may remain intact on the sidewalls of the solder material 102 for continuously inhibiting solder spreading.

Preferably, the coating 104 may comprise for example a morphological adhesion promoter made of a porous material. The structure of a coating 104 embodied as morphological adhesion promoter is shown in a detail 152. Alternatively, the coating 104 may comprise an oxide layer, such as copper oxide.

For example, the solder material 102 has a thickness D in a range from 10 μm to 50 μm. In contrast to this, the coating 104 may have a much smaller thickness d in a range from 50 nm to 200 nm. This may ensure a reliable solder connection, an efficient protection against solder spreading, and may permit easy disruption of the coating 104 at a solder surface.

For example, coating 104 on pre-plated solder material 102 may intentionally break when the solder material 102 (for instance tin) melts. The coated surface provided by coating 104 on solder material 102 and landing pad 150 of carrier 118 may prevents tin spreading. Furthermore, coating 104, being embodied as adhesion promoter, may improve mold adhesion when the structure shown in FIG. 1—after soldering—is encapsulated, for instance by a mold compound (not shown).

FIG. 2 illustrates an electronic device 108 according to an exemplary embodiment. The electronic device 108 may be embodied as power semiconductor package.

The illustrated electronic device 108 comprises a first functional body 110 which can be embodied as carrier 118, for instance a laminate-type carrier or a leadframe type carrier. A landing pad 150 of the carrier 118 may be formed in a surface region of the first functional body 110 and may function as solder partner when forming a solder connection by solder structure 100 thereon.

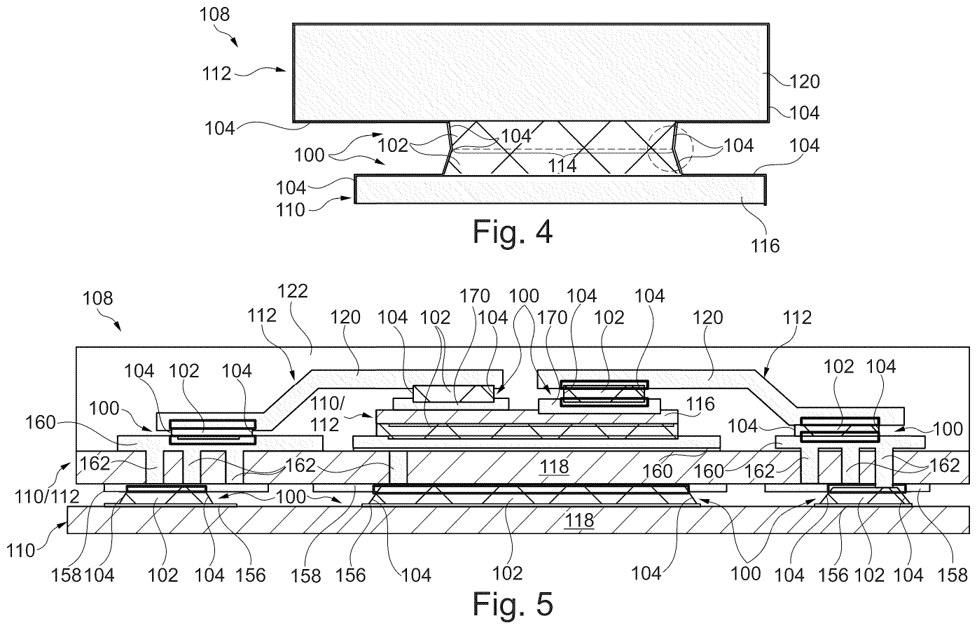

Furthermore, the electronic device 108 comprises a second functional body 112 with a solderable structure 106. The second functional body 112 may for instance be embodied as electronic component 116, for example a semiconductor power chip. Alternatively, the second functional body 112 may be a clip (see reference sign 120 in FIG. 4), i.e. a metal plate. The solderable structure 106 may for instance be a solderable tin pad.

Moreover, a solder structure 100 comprising solder material 102 is provided which establishes a solder connection in a solder connection region 114 between the first functional body 110 and the second functional body 112. To put it shortly, the solder connection region 114 corresponds to the connection surface between the first functional body 110 with its solder structure 100 and the second functional body 112. At said connection surface, a direct physical contact is established between the solder material 102 and the solderable structure 106 of the second functional body 112.

As shown in FIG. 2, a coating 104 of the solder structure 100 partially coats the solder material 102 apart from the solder connection region 114. Preferably, coating 104 is embodied as morphological adhesion promoter. Coating 104 may also coat landing pad 150, as also in FIG. 1. The coating 104 may be configured for protecting the solder material 102 against solder spreading, i.e. may prevent in particular a lateral flow of solder material 102 when being flowable during soldering. This may avoid the undesired phenomenon according to which solder material 102 may flow to undesired regions of the electronic device 108 and may thereby form undesired electric connections. Hence, coating 104 may improve the reliability of a correct functioning of the electronic device 108. Advantageously, this may be achieved even when no solder mask is applied at the electronic device 108. Omitting a solder mask or solder resist may allow to overcome conventional shortcomings, such as the risk of solder joints cracks.

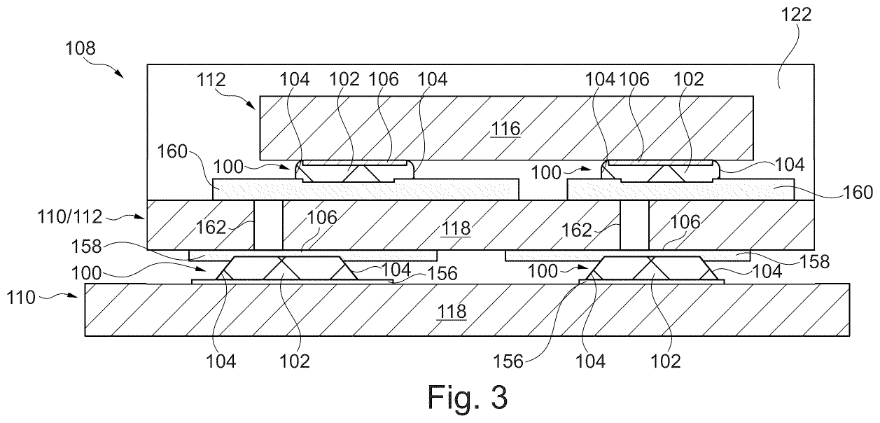

As shown, the coating 104 of the solder structure 100 coats sidewalls of the solder material 102 and a connected horizontal surface portion of the solder material 102 apart from the solderable structure 106. Furthermore, the coating 104 covers the entire exposed surface of the landing pad 150. While the coating 104 on the sidewalls of the solder material 102 prevents solder spreading, the coating 104 both on the solder material 102 and on the landing pad 150 also functions as adhesion promoter for promoting adhesion with an encapsulant (see reference sign 122 in FIG. 3), for instance a mold compound, which may encapsulate at least part of the functional bodies 110, 112 and the solder structure 100.

For manufacturing the electronic device 108 of FIG. 2, it is for instance possible to provide the solder structure 100 of FIG. 1 on the carrier 118 of the first functional body 110. Additionally or alternatively, it may be possible to provide a solder structure 100 with the described properties on the second functional body 112.

Thereafter, it may be possible to establish a solder connection by the solder material 102 in the solder connection region 114 between the first functional body 110 and the second functional body 112. Advantageously, the coating 104 may be disrupted in a self-destructive way in the solder connection region 114 during the soldering process. This may be the consequence of the soldering conditions (in particular temperature, pressure and/or presence of a solder flux) in the soldering connection region 114 during the soldering process. By the disruption of the coating 104 in the soldering connection region 114, a solder connection may be formed between the first functional body 110 and the second functional body 112 in the soldering connection region 114 with low contact resistance. As the same time, it may be possible to protect the solder material 102, by the coating 104 on the sidewalls of the solder structure 100, against lateral solder spreading during establishing the solder connection. Establishing said solder connection may be accomplished by heating the solder material 102 above its melting point which disrupts the coating 104 in the solder connection region 114. For instance, the solder material 102 may be heated to a temperature in a range from 240° C. to 260° C. during soldering which disrupts the coating 104 in the solder connection region 114. Advantageously, formation of the solder connection and disruption of the coating 104 in the solder connection region 114 may be accomplished by reflow soldering.

Descriptively speaking, the coating 104 (in particular of a metal oxide or an inorganic adhesion promoter) on a tin-comprising surface of the solder structure 100 may crumple and break as the tin material is melted during solder reflow, thus allowing flux to react and promote solder wetting.

FIG. 3 illustrates an electronic device 108 according to another exemplary embodiment.

In the electronic device 108 according to FIG. 3, a plurality of solder connections are created.

For example, a printed circuit board (PCB) may form a bottom-sided first functional body 110 of the electronic device 108. Pads 156 on a top side of said first functional body 110 may be solder-connected with pads 158 on a bottom side of a second functional body 112 being embodied here as a substrate core body (or alternatively as a leadframe). Two solder connections are established between said first and second functional bodies 110, 112 by respective solder structures 100. Each of said solder structure 100 may be constructed for instance as described above, for example referring to FIG. 1 or FIG. 2. The pads 158 are electrically connected with further pads 160 on a top side of the substrate core body by metallic vias 162.

Furthermore, the substrate core body (functioning as second functional body 112 in relation to the PCB-type first functional body 110 on the bottom of FIG. 3) may also function as bottom-sided first functional body 110 being solder connected with an electronic component 116 functioning as second functional body 112. The electronic component 116 may for example be a semiconductor chip. The pads 160 on the top side of the substrate core body may be connected with pads or solderable structure 106 on a bottom side of the chip-type second functional body 112 by further solder structures 100 (which may be constructed as described above, for instance referring to FIG. 1 or FIG. 2).

Any of the electrically conductive pads of any of the functional bodies 110, 112 of FIG. 3 may also be embodied as bump or pillar.

Furthermore, the electronic device 108 of FIG. 3 comprises an encapsulant 122 which may encapsulate part of the constituents of the electronic device 108. For example, encapsulant 122 may be a mold compound. In the shown example, encapsulant 122 encapsulates part of the substrate core body, the electronic component 116 as well as the solder structures 100 in between. Advantageously, adhesion promoter-type coating 104 of said solder structures 100 may improve adhesion of the encapsulant 122 to the solder structures 100 and may synergistically function as a protection against solder spreading.

In the electronic device 108 of FIG. 3, no solder resist is present or needed, thanks to the solder spreading inhibiting coating 104 of the solder structures 100.

FIG. 4 illustrates an electronic device 108 according to still another exemplary embodiment.

In this embodiment, the bottom-sided first functional body 110 may be an electronic component 116 (a pad thereof is shown in FIG. 4). Moreover, the top-sided second functional body 112 of FIG. 4 may be a clip 120, for instance embodied as a curved metal plate.

In the embodiment of FIG. 4, two solder structures 100 are provided at an interface between the first functional body 110 and the second functional body 112. Each solder structure 100 can be constructed as described above, for example referring to FIG. 1 or FIG. 2. Before connecting the functional bodies 110, 112 with each other by soldering, a first of said solder structures 100 may be formed on a top side of the first functional body 110. Correspondingly, a second of said solder structures 100 may be formed on a bottom side of the second functional body 112. Thereafter, the solder structures 100, 100 may be connected by soldering, preferably reflow soldering. During said soldering process, the portions of the coatings 104, 104 of the solder structures 100, 100 at solder connection region 114 may be disrupted so that their solder material 102, 102 will be joint. During this process, the portions of the coating 104, 104 at the sidewalls of the solder structures 100, 100 protect the solder materials 102, 102 against lateral solder spreading. Furthermore, the remaining sidewall portions of the coatings 104, 104, which may be made of an adhesion promoting material, may improve adhesion with an encapsulant 122 (not shown in FIG. 4) which may encapsulate the illustrated constituents of the electronic device 108. Furthermore, coating 104 may also be present on exposed surfaces of the first functional body 110 and/or the second functional body 112, for instance for the purpose of adhesion promotion.

The latter mentioned surfaces being not coated with tin may remain stable during the reflow process. Coating 104 in the solder connection region 114 may crumple and break as the tin material is melted from both sides. Said melting will occur during solder reflow, thus allowing flux to react and promote solder wetting.

FIG. 5 illustrates an electronic device 108 according to yet another exemplary embodiment.

The electronic device 108 according to FIG. 5 differs from the electronic device 108 according to FIG. 4 in particular in that, according to FIG. 5, clips 120 are provided as additional uppermost second functional bodies 112. In FIG. 5, pads 170 on the top side of the electronic component 116 are connected by the clips 120 and via further solder structures 100 with the central substrate core body (i.e. the upper one of the carriers 118 shown in FIG. 5).

Coating 104 for protecting solder material 102 against solder spreading, being disrupted selectively in a respective solder connection region 114, and being configured for promoting adhesion may be formed on surfaces of the solder material 102 and optionally also partially or entirely on surfaces of the clips 120 and/or on at least part of the pads 156, 158, 160, 170.

Disruptive coating 104 on solder material 100 (for instance tin or a solder plated surface) may be used for component package input/output pad bonding interconnect.

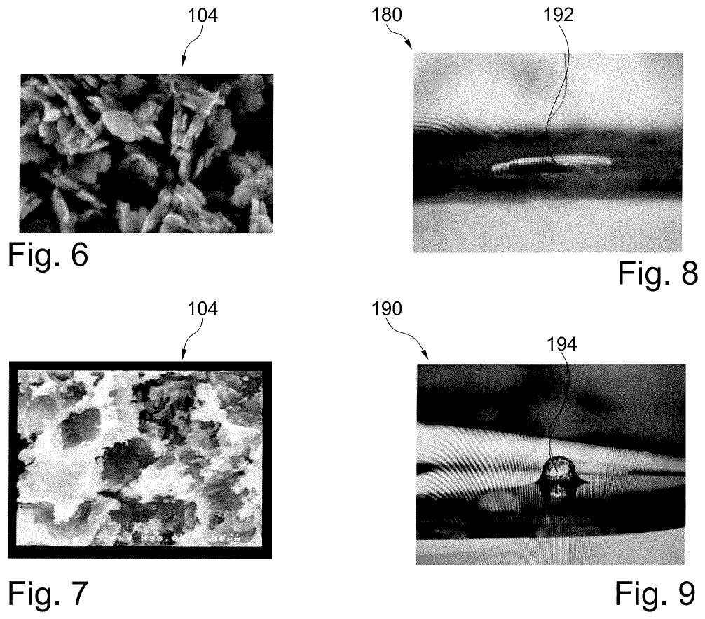

FIG. 6 illustrates an image of a morphological adhesion promoter as coating 104 of a solder structure 100 according to an exemplary embodiment. FIG. 6 shows a BOT surface being selective by nature.

FIG. 7 illustrates another image of a morphological adhesion promoter as coating 104 of a solder structure 100 according to an exemplary embodiment. FIG. 7 shows a chromium free coating 104.

FIG. 8 illustrates an image showing a bare leadframe surface subjected to solder spreading. More specifically, FIG. 8 shows a bare leadframe surface without specific treatment. The shown solder structure 192 strongly spreads over the surface.

FIG. 9 illustrates another image showing protection against solder spreading in an electronic device 108 according to an exemplary embodiment. The shown solder structure 194 does not experience spreading over the surface of the leadframe thanks to its coverage with a morphological adhesion promoter.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A solder structure which comprises:
a solder material; and
a coating which at least partially coats the solder material and is configured for protecting the solder material against solder spreading and for being at least partially disrupted when establishing a solder connection between the solder material and a solderable structure.

2. The solder structure according to claim 1, wherein the coating comprises an adhesion promoter.

3. The solder structure according to claim 1, wherein the coating comprises an inorganic and/or a morphological adhesion promoter.

4. The solder structure according to claim 2, wherein the adhesion promoter comprises a porous material.

5. The solder structure according to claim 1, wherein the coating comprises an oxide layer.

6. The solder structure according to claim 5, wherein the oxide layer comprises at least one of the group consisting of a metal oxide, in particular copper oxide, aluminum oxide, zinc oxide chromium oxide, zinc oxide vanadium oxide, zinc oxide molybdenum oxide, zinc oxide manganese oxide, zinc oxide tungsten oxide, and a semiconductor oxide, in particular silicon oxide.

7. The solder structure according to claim 1, wherein the solder material has a thickness in a range from 5 μm to 100 μm, in particular in a range from 10 μm to 50 μm.

8. The solder structure according to claim 1, wherein the coating has a thickness in a range from 10 nm to 500 nm.

9. The solder structure according to claim 1, wherein the solder material comprises tin or a tin alloy, in particular at least one of the group consisting of AgSn, AuSn, NiSn, CuSn, AgCuSn, and InSn.

10. An electronic device, comprising:
a first functional body;
a second functional body; and
a solder structure comprising solder material which establishes a solder connection in a solder connection region between the first functional body and the second functional body;
wherein a coating of the solder structure partially coats the solder material apart from the solder connection region; and
wherein the coating is configured for protecting the solder material against solder spreading.

11. The electronic device according to claim 10, wherein one of the first functional body and the second functional body is an electronic component and the other one of the first functional body and the second functional body is a carrier.

12. The electronic device according to claim 10, wherein one of the first functional body and the second functional body is a clip and the other one of the first functional body and the second functional body is a carrier.

13. The electronic device according to claim 11, wherein the carrier is a laminate substrate or a leadframe structure.

14. The electronic device according to claim 11, wherein the carrier comprises a metal structure, in particular a metal structure with a metallic surface coating.

15. The electronic device according to claim 10, wherein one of the first functional body and the second functional body is an electronic component and the other one of the first functional body and the second functional body is a clip.

16. The electronic device according to claim 10, wherein the electronic device is free of a solder resist.

17. The electronic device according to claim 10, wherein the coating of the solder structure coats at least sidewalls of the solder material.

18. The electronic device according to claim 10, comprising at least one of the following features:
wherein the solder structure forms part of one or both of the first functional body and the second functional body;
configured as a semiconductor power package;
comprising an encapsulant at least partially encapsulating the first functional body, the second functional body, and the solder structure.

19. A method of manufacturing an electronic device, the method comprising:
providing a solder structure according to claim 1 between a first functional body and a second functional body;
establishing a solder connection by the solder material in a solder connection region between the first functional body and the second functional body while at least partially disrupting the coating in the solder connection region; and
protecting the solder material by the coating against solder spreading during establishing the solder connection.

20. The method according to claim 19, comprising at least one of the following features:
wherein the method comprises establishing the solder connection by heating the solder material above its melting point which at least partially disrupts the coating in the solder connection region;
wherein the method comprises establishing the solder connection by heating the solder material to a temperature in a range from 230° C. to 270° C., in particular in a range from 240° C. to 260° C., which at least partially disrupts the coating in the solder connection region;
wherein the method comprises establishing the solder connection and at least partially disrupting the coating in the solder connection region by reflow soldering.
